(19) United States
(12) Patent Application Publication
(10) Pub. No.: US 2012/0188737 A1
(43) Pub. Date: Jul. 26, 2012

(54) MOTHERBOARD AND MEMORY CONNECTOR THEREOF

(75) Inventors: Yu-Chang PAI, Tu-Cheng (TW); Yung-Chieh CHEN, Tu-Cheng (TW)

(73) Assignee: HON HAI PRECISION INDUSTRY CO., LTD., Tu-Cheng (TW)

(21) Appl. No.: 13/033,607

(22) Filed: Feb. 24, 2011

(30) Foreign Application Priority Data
Jan. 20, 2011 (TW) 100102108

(51) Int. Cl. H05K 7/00; H01R 24/00

(52) U.S. Cl. 361/783; 439/630

(57) ABSTRACT

A motherboard includes a printed circuit board (PCB) and a memory connector. The PCB includes top and bottom layers. A number of pads are set on the sides of the top and bottom layers and connected to a memory controller. A number of metal pins are set on a first sidewall of the memory connector. A socket slot is defined in a second sidewall opposite to the first sidewall. Top and bottom sidewalls bounding the socket slot define a number of grooves. First ends of the metal pins are soldered on the pads of the top layer and the bottom layer of the PCB. Second ends of the metal pins are extended to the socket slot through the memory connector and exposed through the grooves of the memory connector, to be electrically connected to the golden fingers of a memory when the memory is inserted in the socket slot.

### BACKGROUND

1. Technical Field

The present disclosure relates to a motherboard and a memory connector of the motherboard.

2. Description of Related Art

In some notebook computers, memory chips are soldered on motherboards to reduce the thickness. However, the memory chips for these notebook computers cannot be changed. In other notebook computers, the memory chips are not soldered onto the motherboard but are inserted into sockets that allow the memory chips to be almost stacked on the motherboard. However, the memory chips or slots still increase the height of the motherboard. Therefore there is room for improvement in the art.

### BRIEF DESCRIPTION OF THE DRAWINGS

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the several views.

FIG. 1 is an exploded, isometric view of a motherboard in accordance with an exemplary embodiment of the present disclosure.

FIG. 2 is an assembled, isometric view of the motherboard of FIG. 1.

FIG. 3 is a cross-sectional view of the motherboard of FIG. 2.

### DETAILED DESCRIPTION

The disclosure, including the drawings, is illustrated by way of example and not by limitation. It should be noted that references to “an” or “one” embodiment in this disclosure are not necessarily to the same embodiment, and such references mean at least one.

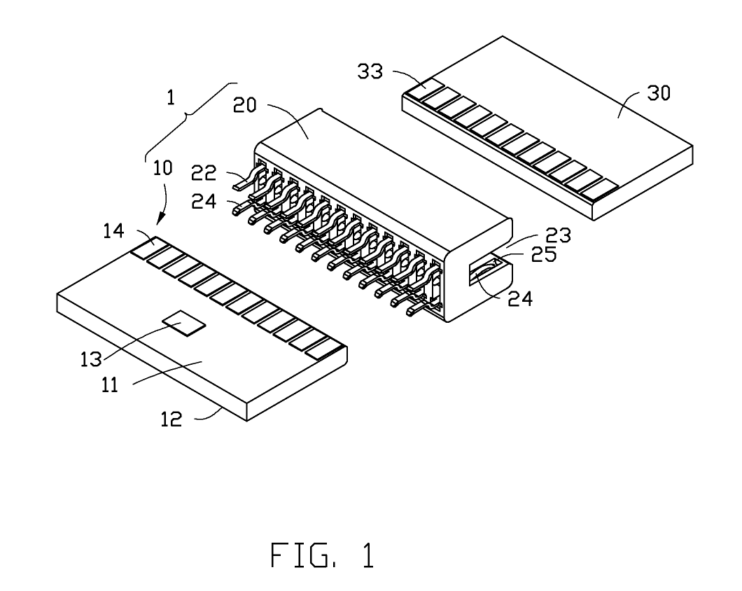

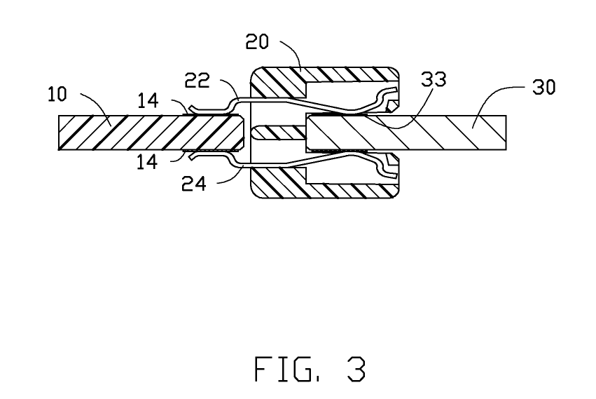

Referring to FIG. 1 and FIG. 3, a motherboard 1 in accordance with an exemplary embodiment includes a printed circuit board (PCB) 10 and a memory connector 20. The PCB 10 includes a top layer 11 and a bottom layer 12. Other layers of the PCB 10 between the top layer 11 and the bottom layer 12 are not shown. A plurality of pads 14 is set on corresponding sides of the top layer 11 and the bottom layer 12. A memory controller 13 is set on the top layer 11. Other elements, such as central processing unit sockets (not shown) are set on the top layer 11. The pads 14 are electrically connected to the memory controller 13.

The memory connector 20 is substantially U-shaped, and defines a socket slot 23 in a first sidewall. Top and bottom sidewalls bounding the socket slot 23 define a plurality of grooves 25. A plurality of metal pins 22 and 24 arranged in two rows extending from a second sidewall of the memory connector 20 opposite to the first sidewall. The metal pins 22 and 24 are resilient metal pieces. The length of the socket slot 23 and the length of the memory connector 20 are the same as the length of a memory 30. The height of the socket slot 23 is equal to or slightly larger than thickness of the memory 30, to receive the memory 30. The first ends of the metal pins 22 are soldered on the corresponding pads 14 of the top layer 11 of the PCB 10, to be electrically connected to the pads 14. The second ends of the metal pins 22 and 24 are extended to the socket slot 23 and exposed through the grooves 25 of the socket slot 23, to be electrically connected to golden fingers 33 of the memory 30 when the memory 30 is inserted in the socket slot 23. In one embodiment, a number of the pads 14 and a number of the metal pins 22 and 24 of the memory connector 20 are same as a number of the golden fingers 33 of the memory 30.

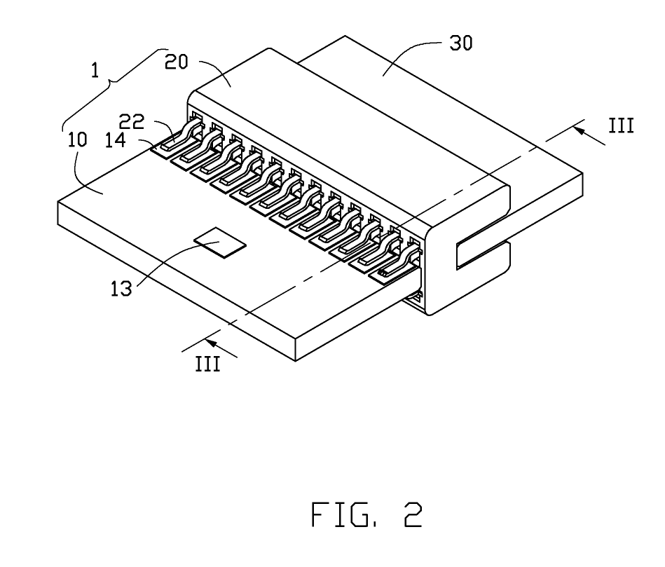

Referring to FIG. 2, when the memory 30 is inserted in the socket slot 23, due to the metal pins 22 and 24 of the memory connector 20 being connected to the pads 14 of the PCB 10, the memory controller 13 can communicate with the memory 30 through the pads 14 and the memory connector 20. When the memory 30 is inserted in the memory connector 20, the memory 30 is substantially coplanar with to the PCB 10.

The height of the motherboard 1 will not change when the memory 30 is inserted in the memory connector 20.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A motherboard comprising:
a printed circuit board (PCB) comprising:
a top layer;
a bottom layer;
a memory controller set on the top layer; and
a plurality of pads set on corresponding sides of the top layer and the bottom layer, and electrically connected to the memory controller; and
a memory connector defining a socket slot in a first sidewall and comprising a plurality of metal pins extending from a second sidewall opposite to the first sidewall, top and bottom sidewalls bounding the socket slot defining a plurality of grooves, first ends of the metal pins soldered on the pads of the top layer and the bottom layer of the PCB, second ends of the metal pins extended to the socket slot through the memory connector and exposed through the grooves, to be electrically connected to golden fingers of a memory when the memory is inserted in the socket slot to be coplanar to the PCB.

2. The motherboard as claimed in claim 1, wherein the memory connector is substantially U-shaped, a length of the socket slot and a length of the memory connector are the same as a length of the memory, a height of the socket slot is equal to or slightly larger than thickness of the memory.

3. The motherboard as claimed in claim 1, wherein the metal pins of the memory connector are arranged in two rows, respectively soldered on the pads of the top layer and the bottom layer of the PCB.

4. The motherboard as claimed in claim 1, wherein a number of the metal pins of the memory connector is same as a number of the golden fingers of the memory and a number of the pads of the top layer and the bottom layer of the PCB.

5. The motherboard as claimed in claim 1, wherein the metal pins of the memory connector are resilient metal pieces.

6. A memory connector applicable to connect a memory to a printed circuit board (PCB), the memory connector defining a socket slot in a first sidewall and comprising a plurality of metal pins extending from a second sidewall opposite to the first sidewall, wherein top and bottom sidewalls bounding the socket slot define a plurality of grooves, first ends of the metal pins are configured to be soldered on pads of a top layer and a bottom layer of the PCB, second ends of the metal pins are extended to the socket slot through the memory connector and exposed through the grooves of the memory connector, to be electrically connected to golden fingers of a memory when the memory is inserted in the socket slot.

7. The memory connector as claimed in claim 6, wherein the memory connector is substantially U-shaped, a length of the socket slot and a length of the memory connector are same as a length of the memory, height of the socket slot is equal to or slightly larger than thickness of the memory.

8. The memory connector as claimed in claim 6, wherein the metal pins are arranged in two rows, respectively to be soldered on the pads of the top layer and the bottom layer of the PCB.

9. The memory connector as claimed in claim 6, wherein a number of the metal pins of the memory connector is same as a number of the golden fingers of the memory and a number of the pads of the top layer and the bottom layer of the PCB.

10. The memory connector as claimed in claim 6, wherein the metal pins of the memory connector are resilient metal pieces.
